(19) United States
(12) Patent Application Publication
(10) Pub. No.: US 2011/0157798 A1
(43) Pub. Date: Jun. 30, 2011

(54) PORTABLE ELECTRONIC APPARATUS

(75) Inventors: Yasutoshi Kawai, Osaka (JP); Takahiro Kitai, Osaka (JP); Yasuhiro Kato, Osaka (JP)

(73) Assignee: SANYO ELECTRIC CO., LTD., Osaka (JP)

(21) Appl. No.: 12/977,566

(22) Filed: Dec. 23, 2010

(30) Foreign Application Priority Data
Dec. 28, 2009 (JP) 2009-297717

(51) Int. Cl. H05K 5/00

(52) U.S. Cl. 361/679.01

(57) ABSTRACT

The present invention provides a portable electronic apparatus in which a control circuit that controls an apparatus operation and/or an integrated circuit that generates heat when driven are provided in a casing having a grip portion to be gripped by a hand, wherein the control circuit and/or the integrated circuit are placed in a region different from an inner region of the grip portion, in an inner region of the casing.

This patent application claims the priority of Japanese Patent Application No. 2009-297717, which is incorporated in the disclosure by reference.

### BACKGROUND OF THE INVENTION

1. Field of the Invention

The present invention relates to a portable electronic apparatus such as a camera or a mobile phone.

2. Description of the Related Art

Conventionally, a portable electronic apparatus has been proposed in which a control circuit that controls an apparatus operation is provided in a casing having a grip portion to be gripped by a hand. For example, there is a video camera in which a casing including an image pickup mechanism, and a second casing including a liquid crystal display are connected openably and closably with respect to each other by a two-axis hinge mechanism. In the video camera having such a configuration, a grip portion is formed in a region in the casing including the image pickup mechanism, the region facing the second casing with the second casing being closed with respect to the casing.

However, in the conventional portable electronic apparatus, a control circuit is provided in various regions in a casing. In particular, in a portable electronic apparatus having a grip portion, at least a part of a control circuit is provided in an inner region of the grip portion. Thus, if an apparatus operation is performed and a large amount of heat is generated from the control circuit, heat is easily transferred to a hand gripping the grip portion, and the heat transferred to the hand may force an operator to stop the operation of the portable electronic apparatus.

### SUMMARY OF THE INVENTION

The present invention provides a portable electronic apparatus in which a control circuit that controls an apparatus operation and/or an integrated circuit that generates heat when driven are provided in a casing having a grip portion to be gripped by a hand, wherein the control circuit and/or the integrated circuit are placed in a region different from an inner region of the grip portion, in an inner region of the casing.

### BRIEF DESCRIPTION OF THE DRAWINGS

FIG. 1 is a perspective view of a video camera in a second opened state according to an embodiment of the present invention seen from a front side;

FIG. 2 is a perspective view of the video camera in the second opened state seen from a back side;

FIG. 3 is a side view of the second opened state of the video camera;

FIG. 4 is a front view of a first opened state of the video camera;

FIG. 5 is a back view of a closed state of the video camera;

FIG. 6 is an exploded perspective view of a first casing included in the video camera;

FIG. 7 is a plan view of an inside of the first casing seen from a side of a third cabinet component;

FIG. 8 is a sectional view taken along the line A-A in FIG. 7; and

FIG. 9 is an exploded perspective view showing a circuit board, a chassis body, and a resin sheet provided in the first casing.

### DETAILED DESCRIPTION OF THE PREFERRED EMBODIMENTS

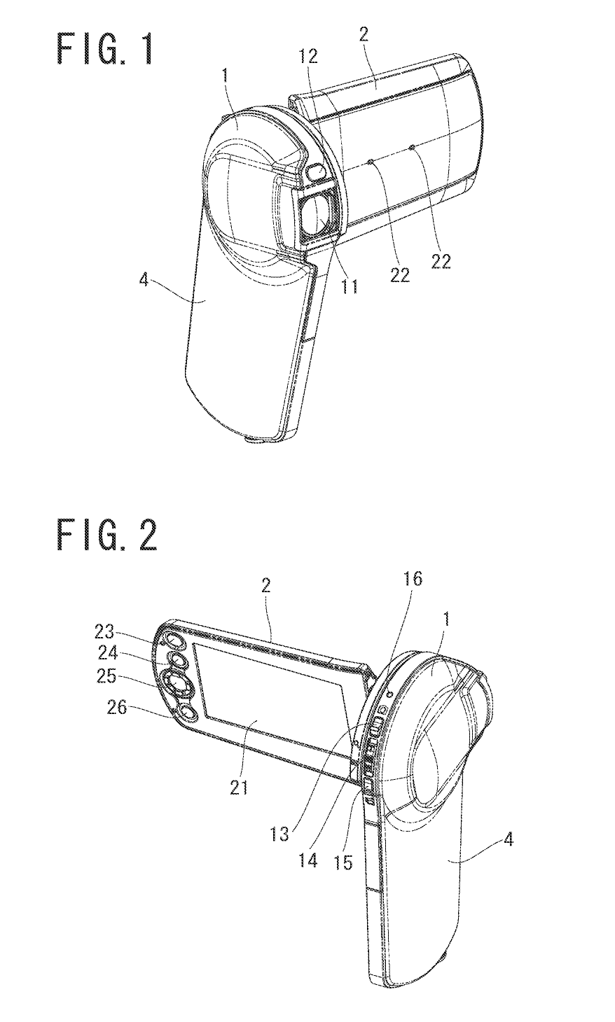

Now, the present invention embodied as a video camera that can photograph still images and moving images will be described in detail with reference to the drawings. As shown in FIGS. 1 and 2, a video camera according to an embodiment of the present invention includes a first casing 1 and a second casing 2.

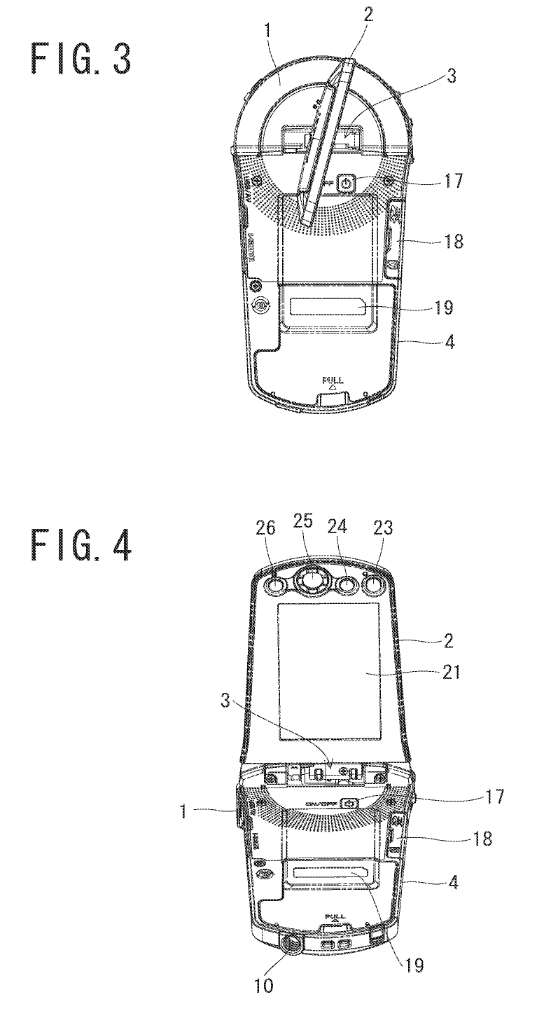

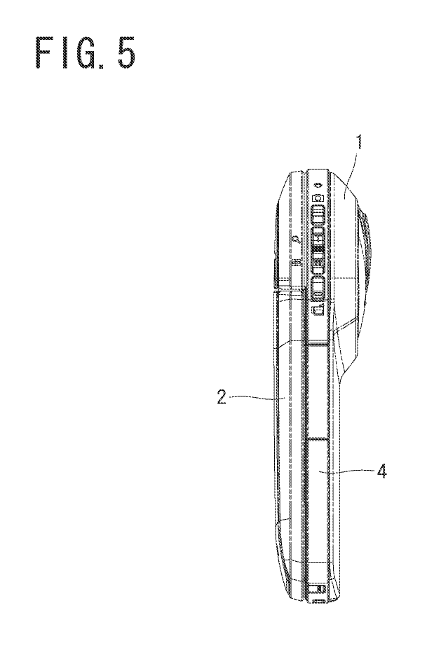

The casings 1 and 2 are connected openably and closably with respect to each other by a two-axis hinge mechanism 3 as shown in FIG. 3. The video camera can be set to a closed state in which the second casing 2 is closed with respect to the first casing 1 as shown in FIG. 5, a first opened state in which the second casing 2 is opened with respect to the first casing 1 as shown in FIG. 4, and a second opened state in which the second casing 2 is pivoted from the first opened state as shown in FIGS. 1 to 3.

As shown in FIG. 5, in the first casing 1, a grip portion 4 is formed in a region facing the second casing 2 when the video camera is set to the closed state. The video camera is used when the video camera is set to the second opened state as shown in FIGS. 1 to 3 and the grip portion 4 is gripped by a hand.

As shown in FIG. 4, a mounting seat 10 to which a tripod (not shown) is mounted is provided in a bottom portion of the first casing 1. On the mounting seat 10, a female thread is formed into which a male thread formed on the tripod is screwed, and the female screw is exposed on a bottom surface of the first casing 1. The video camera is mounted to the tripod using the mounting seat 10, thereby allowing the video camera to be placed and used on a floor or the ground.

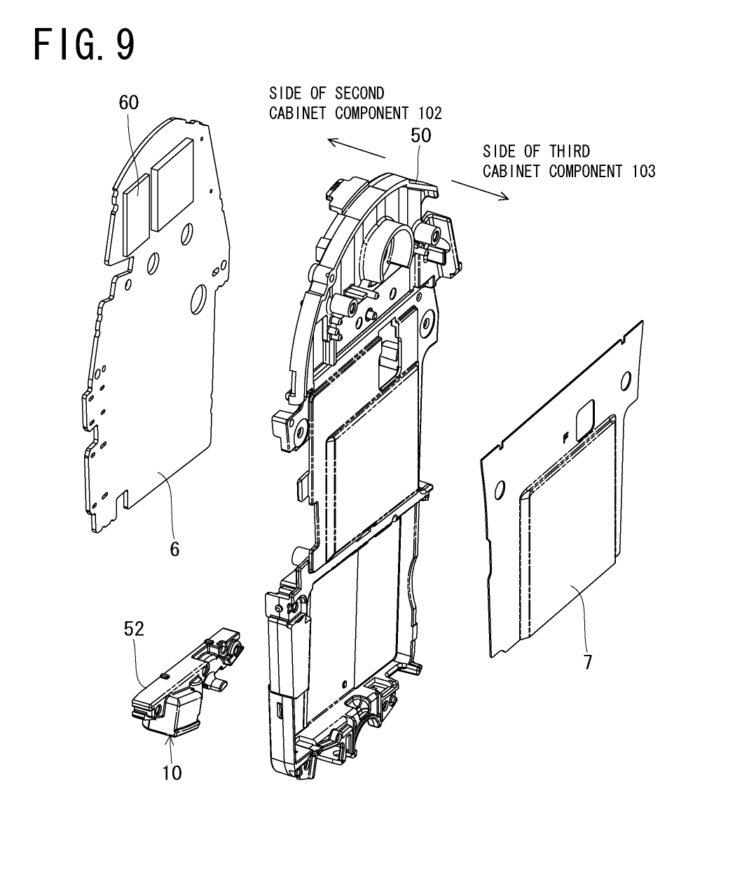

The mounting seat 10 is formed on a separate member 52 mounted to a lower end position of a chassis body 50 described later as shown in FIG. 9.

In a front portion of the first casing 1, as shown in FIG. 1, a taking lens 11 and an LED (Light Emitting Diode) 12 for illumination are provided. In a rear portion of the first casing 1, as shown in FIG. 2, a shutter button 13 for instructing still image photographing, a zoom button 14, a recording button 15 for instructing moving image photographing, and an access lamp 16 are provided.

On a surface of the grip portion 4 of the first casing 1, as shown in FIGS. 3 and 4, a power supply button 17, a card lid 18, and a battery lid 19 are provided in a region covered by the second casing 2 when the video camera is set to the closed state.

On an outer surface of the second casing 2, as shown in FIG. 1, a pair of microphones 22 and 22 are provided. On an inner surface of the second casing 2, as shown in FIG. 2, a liquid crystal display 21 is provided, and a recording/playback key 23, a menu key 24, a cross key 25, and a set key 26 are also provided in a region different from a region where the liquid crystal display 21 is provided. The outer surface of the second casing 2 is plated.

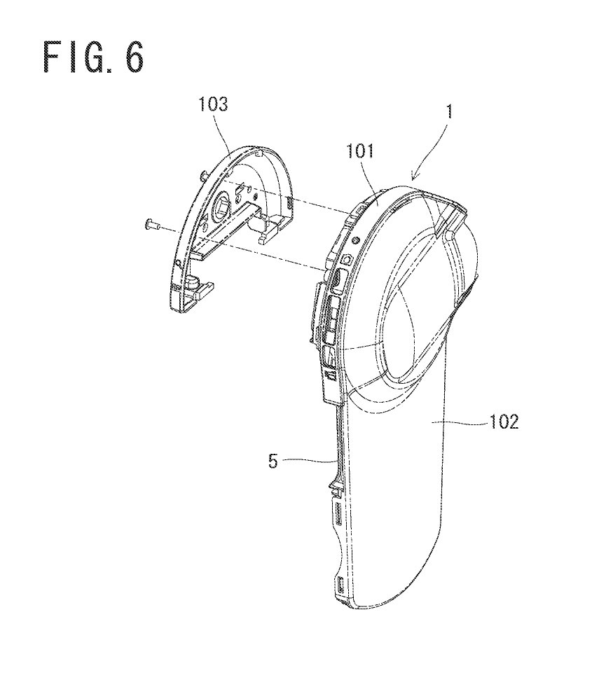

As shown in FIG. 6, the first casing 1 includes a first cabinet component 101 that constitutes a curved upper wall of the first casing 1, a second cabinet component 102 that constitutes a right side wall of the first casing 1 in FIG. 6, and a third cabinet component 103 that constitutes an upper left side wall of the first casing 1 in FIG. 6, all mounted to a chassis 5. The first cabinet component 101 and the third cabinet component 103 are made of synthetic resin, while the second cabinet component 102 is made of aluminum.

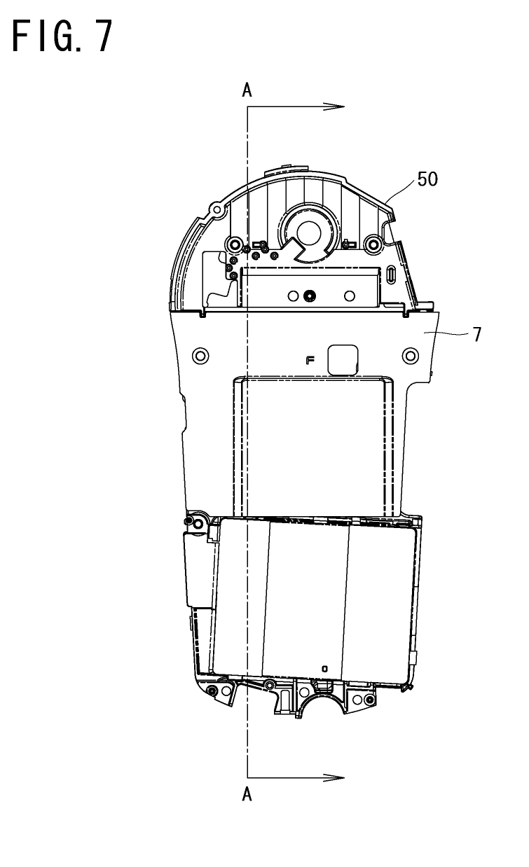

As shown in FIG. 7, the chassis 5 has a chassis body 50, and the first cabinet component 101, the second cabinet component 102, and the third cabinet component 103 are mounted to the chassis body 50. The chassis body 50 is made of magnesium. Since magnesium has higher thermal conductivity than aluminum or synthetic resin, the chassis body 50 has higher thermal conductivity than the first casing 1.

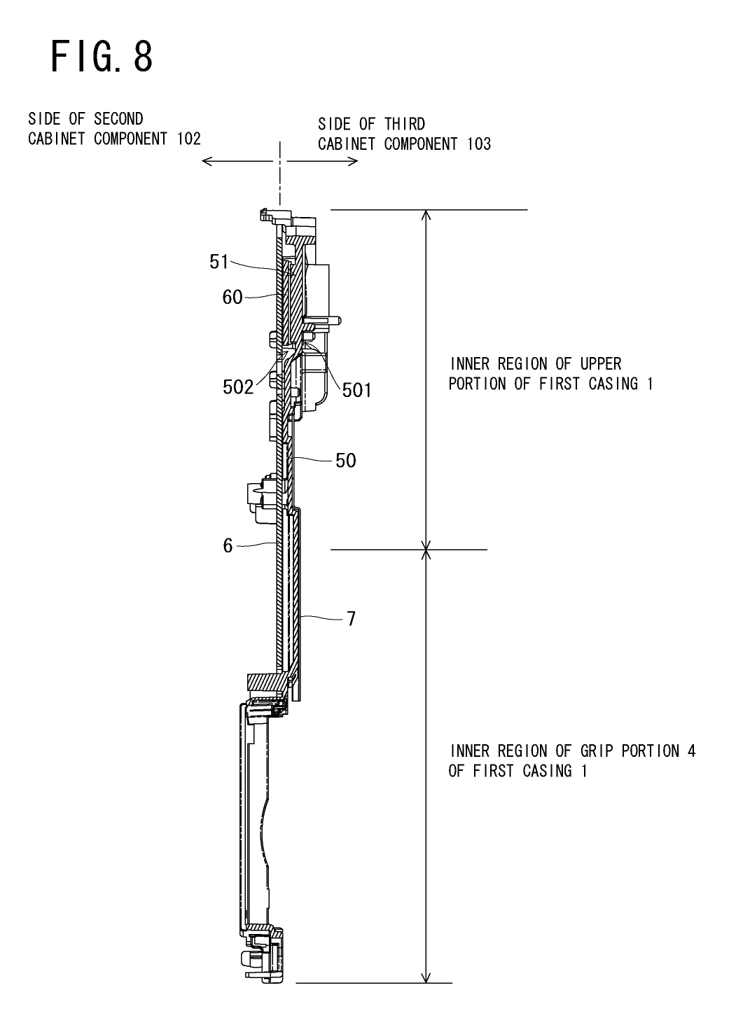

As shown in FIG. 8, an upper portion 501 of the chassis body 50 is bent into a crank shape toward the third cabinet component 103.

On a surface of the chassis body 50 on a side of the second cabinet component 102, a circuit board 6 is provided, and a gap 502 is formed between the upper portion 501 of the chassis body 50 and the circuit board 6. The gap 502 is placed in a region different from an inner region of the grip portion 4, specifically, in an inner region of an upper portion of the first casing 1, in an inner region of the first casing 1.

As shown in FIG. 8 (also see FIG. 9), on a surface of the circuit board 6 on a side of the chassis body 50, an ASIC (Application Specific Integrated Circuit) 60 for controlling an apparatus operation of the video camera is provided in a region where the gap 502 is formed between the circuit board 6 and the upper portion 501 of the chassis body 50. Thus, the ASIC 60 is housed in the gap 502, and placed in a region different from the inner region of the grip portion 4, in the inner region of the first casing 1.

As shown in FIG. 8, in the upper portion 501 of the chassis body 50, a bump portion 51 is formed on the surface on the side of the circuit board 6, and a tip surface of the bump portion 51 is placed close to a surface of the ASIC 60.

As shown in FIG. 8 (also see FIG. 9), to the chassis body 50, a resin sheet 7 is bonded in a middle region on a surface on the side of the third cabinet component 103. The middle region is a surface region that is hardly covered by a right hand when the grip portion 4 of the first casing 1 is gripped by the right hand. The sheet 7 is made of polycarbonate resin.

In the video camera, when a predetermined apparatus operation is performed, the ASIC 60 generates heat when driven. The ASIC 60 is placed in the region different from the inner region of the grip portion 4, specifically, the inner region of the upper portion of the first casing 1, in the inner region of the first casing 1. Thus, even if the apparatus operation is performed and the ASIC 60 generates a large amount of heat with the grip portion 4 of the first casing 1 being gripped by a hand, only a small amount of heat is transferred to the hand gripping the grip portion 4. This avoids a situation in which the heat transferred to the hand gripping the grip portion 4 forces an operator to stop the operation of the video camera while performing the apparatus operation.

If the heat generated from the ASIC 60 is retained near the ASIC 60, overheating may break the ASIC 60. In the video camera, the heat generated from the ASIC 60 is moved through the bump portion 51 of the chassis body 50 close to the surface of the ASIC 60 to the chassis body 50, and thus the heat is diffused to the entire chassis body 50. This prevents overheating from breaking the ASIC 60.

Further, in the video camera, the resin sheet 7 is bonded to the surface of the chassis body 50. The resin sheet 7 has high emissivity. Thus, the heat generated from the ASIC 60 is transferred through the chassis body 50 to the resin sheet 7, and released from the resin sheet 7 to the outside of the first casing 1 by radiation.

As described above, the resin sheet 7 is placed in the surface region that is hardly covered by the right hand gripping the grip portion 4 in the surface on the side of the third cabinet component 103. Thus, radiant heat from the resin sheet 7 is hardly transferred to the right hand gripping the grip portion 4.

The configuration of the present invention is not limited to the embodiment, but various modifications may be made by those skilled in the art without departing from the spirit of the present invention described in claims. For example, the video camera may have a configuration in which a thermally conductive material is provided between the bump portion 51 of the chassis body 50 and the ASIC 60. With this configuration, the heat generated from the ASIC 60 is more efficiently transferred to the chassis body 50.

The resin sheet 7 may be made of various kinds of resin having high emissivity, not limited to polycarbonate resin. The chassis body 50 may be made of various kinds of metal having high thermal conductivity, not limited to magnesium.

The various configurations adopted in the video camera may be applied to various portable electronic apparatus in which a control circuit such as an ASIC or an integrated circuit that generates heat when driven are provided in a casing.

What is claimed is:

1. A portable electronic apparatus comprising:
a casing having a grip portion to be gripped by a hand; and
a control circuit that is provided in the casing and controls an apparatus operation,
wherein the control circuit is placed in a region different from an inner region of the grip portion, in an inner region of the casing.

2. The portable electronic apparatus according to claim 1, wherein in the casing in which the control circuit is provided, a chassis is provided made of a material having higher thermal conductivity than thermal conductivity of the casing, and the control circuit is placed close to the chassis.

3. The portable electronic apparatus according to claim 2, wherein a resin sheet is bonded to a surface of the chassis.

4. The portable electronic apparatus according to claim 1, wherein a second casing is connected to the casing via a hinge mechanism, and in the casing in which the control circuit is provided, the grip portion is formed in a region facing the second casing in a closed state where the second casing is closed with respect to the casing.

5. The portable electronic apparatus according to claim 4, wherein in the casing in which the control circuit is provided, a chassis is provided made of a material having higher thermal conductivity than thermal conductivity of the casing, and the control circuit is placed close to the chassis.

6. The portable electronic apparatus according to claim 5, wherein a resin sheet is bonded to a surface of the chassis.

7. A portable electronic apparatus comprising:
a casing having a grip portion to be gripped by a hand; and
an integrated circuit that is provided in the casing and generates heat when driven,
wherein the integrated circuit is placed in a region different from an inner region of the grip portion, in an inner region of the casing.
